(19) United States
(12) Patent Application Publication
(10) Pub. No.: US 2023/0244847 A1
(43) Pub. Date: Aug. 3, 2023

(54) NEW RELEASE PROCESS INCLUDING CONSISTENCY CHECKING

(71) Applicant: International Business Machines Corporation, Armonk, NY (US)

(72) Inventors: Eduard Herkel, New York, NY (US); Florian Braun, Wuerselen (DE); Sayaan Mohammed Nawaz, New York, NY (US); Jesse Peter Surprise, Highland, NY (US); OFER GEVA, Poughkeepsie, NY (US)

(21) Appl. No.: 17/591,111

(22) Filed: Feb. 2, 2022

(51) Int. Cl. G06F 30/398

(52) U.S. Cl. CPC G06F 30/398

(57) ABSTRACT

Provided are embodiments for a computer-implemented method, a system, and a computer program product for performing integrity checking during physical design data handoffs. Embodiments can include receiving a file corresponding to a new release for a physical design of an integrated circuit, and performing a syntax check on the file. Embodiments can also include performing a plurality of subsequent checks on the file based on a result of the syntax check, and committing the file based at least in part on a result of the plurality of subsequent checks.

### BACKGROUND

The present invention generally relates to the design and fabrication of integrated circuit chips, and more specifically, to a new release process that includes consistency checking during handoffs.

Integrated circuits are used for a wide variety of electronic applications, from simple devices such as wristwatches to the most complex computer systems. A microelectronic integrated circuit (IC) chip can generally be thought of as a collection of logic cells with electrical interconnections between the cells, formed on a semiconductor substrate (e.g., silicon). An IC may include a very large number of cells and require complicated connections between the cells. A cell is a group of one or more circuit elements such as transistors, capacitors, resistors, inductors, and other basic circuit elements combined to perform a logic function. Cell types include, for example, core cells, scan cells, input/output (I/O) cells, and memory (storage) cells. Each of the cells of an IC may have one or more pins, each of which in turn may be connected to one or more other pins of the IC by wires. The wires connecting the pins of the IC are also formed on the surface of the chip. For more complex designs, there are typically at least four distinct layers of conducting media available for routing, such as a polysilicon layer and three metal layers.

### SUMMARY

Embodiments of the present invention are directed to performing integrity checking during physical design data handoffs. A non-limiting example computer-implemented method includes receiving, at a processor, a file corresponding to a new release for a physical design of an integrated circuit; and performing a syntax check on the file. The non-limiting example computer-implemented method includes performing a plurality of subsequent checks on the file based on a result of the syntax check; and committing the file based at least in part on a result of the plurality of subsequent checks.

Other embodiments of the present invention implement features of the above-described method in computer systems and computer program products.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 depicts a block diagram for performing error checks for a physical design in accordance with one or more embodiments of the invention;

FIG. 2 depicts a flow diagram of a process for performing error checks for a physical design in accordance with one or more embodiments of the invention;

FIG. 3 depicts a block diagram of a system used to perform a plurality of checks during the physical design of an integrated circuit chip according to embodiments of the invention;

FIG. 4 depicts a process flow of a method of fabricating the integrated circuit according to exemplary embodiments of the invention; and

FIG. 5 depicts a processing system for implementing one or more embodiments of the present invention.

The diagrams depicted herein are illustrative. There can be many variations to the diagrams or the operations described therein without departing from the spirit of the invention. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

### DETAILED DESCRIPTION

An integrated circuit (IC) chip is fabricated by first conceiving the logical circuit description, and then converting that logical description into a physical description or geometric layout. This process is executed using a “netlist,” which is a record that includes all of the nets (interconnections), between the cell pins, including information about the various components such as transistors, resistors and capacitors. A layout can include a set of planar geometric shapes in several layers. The layout is then checked to ensure that it meets all of the design requirements, particularly timing requirements. The result is a set of design files known as an intermediate form that describes the layout. The design files are then run through a dataprep process that is used to produce patterns called masks by an optical or electron beam pattern generator. During fabrication, these masks are used to etch or deposit features in a silicon wafer in a sequence of photolithographic steps using a complex lens system that shrinks the mask image. The process of converting the specifications of an electrical circuit into such a layout is called the physical design.

The physical design of the IC requires careful planning and review from multiple teams at different parts of the process. During physical design, the complex layout of the IC is broken up into multiple blocks and assigned to multiple design teams. Each design team may be responsible for different blocks and hierarchies and may be tasked with ensuring that each block meets the requirements of the overall IC chip design.

One or more embodiments of the present invention provide a quality check for a physical design for the development of an integrated circuit chip. This allows for the identification of errors in the layout and efficient handoff between the various physical design teams.

During the development process of the integrated circuit, the handoff from one team to the next team can be a very time-consuming process because it is largely a manual process and numerous checks must be performed to ensure the compatibility amongst the various segments are aligned. The quality checks can easily consume large blocks of time taking days to weeks or to months to complete.

The integration team is tasked with merging the segments from multiple design teams and is further tasked with fixing any breakages resulting from mismatches between the merged data. The integration team, once receiving the data from the teams, attempts to merge the data for the final IC layout. In the event an error is identified in any segment, the process would need to be restarted from the beginning which consumes additional time, and the integration team would repeat the process until an acceptable design is achieved.

Conventionally, the integration team spends a lot of time fixing the breakages (incompatibilities or errors) among the different segments of the layout from each of the design teams. Due to the number of design teams that are required to develop the IC, various issues may arise as data advances through the different phases of development. Missing data, fault data, or bad data may be introduced in the process at any point in the development. Also, since some of the checks may be performed manually by a developer some issues may be missed or overlooked. In some limited circumstances, some checks may not even be performed. Oftentimes, undetected issues may result in further errors in downstream processes that receive the IC layout. In addition, the undetected issues may result in work that is unusable and must be discarded. Therefore, various quality checks should be performed to identify and resolve as many errors as early in the process as possible so the identified errors will not be propagated to any downstream process during development.

The techniques described herein improve the process by automating the quality checks to prevent breakages in the final layout, reduce the amount of time fixing the data breakages and provide for efficient data handoff between the design teams. The technical effects and benefits can also improve the overall yield and designs for processing IC chips.

One or more embodiments of the present invention provide technological improvements over current methods of analyzing a physical design that requires a plurality of quality checks. Disadvantages of contemporary approaches may include performing a complex and time-consuming manual review process. One or more embodiments of the present invention provide technical solutions to the disadvantages of existing solutions by analyzing segments from each design team and identifying errors prior to merging the data for further development of the layout and production of the IC.

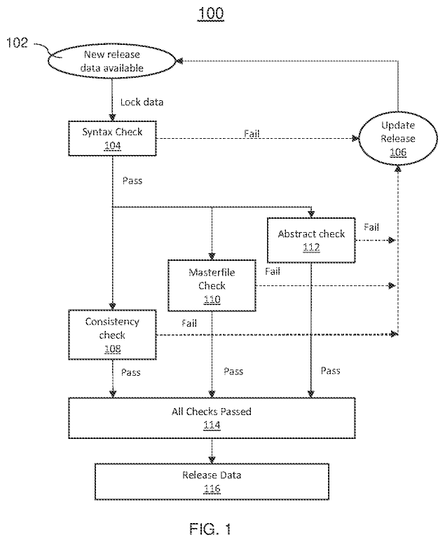

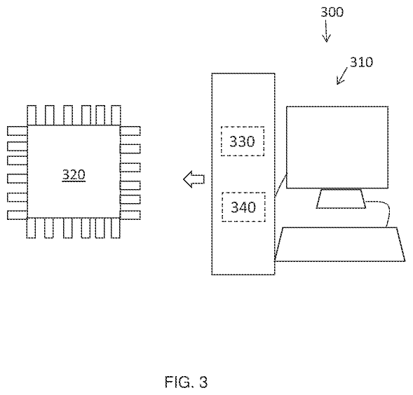

Turning now to FIG. 1, an overview of a process flow 100 for performing the plurality of checks is generally shown in accordance with one or more embodiments of the present invention. The new release data may be processed by a system (such as that discussed with reference to any FIGS. 3-5) at block 102. The new release data can correspond to a new physical design or layout for an IC. The system is configured to perform a syntax check, as shown in block 104, for the text in the file. In one or more embodiments of the invention, the text file may be a JavaScript Object Notation (JSON) file. It can be appreciated that other file types may be used in the process flow 100 and is not limited by the examples described herein. The text file can be a son file that includes references to the libraries storing data such as the timing rules/abstracts/layouts. For the subsequent checks, the .json files are analyzed and the actual checking mechanism are executed on the library data. The file may include the syntax for various parameters, tags, variables, operators, etc. can be checked prior to performing additional checks on the new release data. The system analyzes the text of the file to search for any syntax errors such as improper operators or additional spaces. In the event an error is found, the integrity check fails, and the process returns to block 106. The release data can be updated to correct the error. In one or more embodiments of the invention, the updated release data is provided to the system, and the syntax check can be performed again.

If the syntax check is successful (no syntax errors in the text have been identified), the process proceeds to blocks 108, 110, 112 to perform additional checks. The checks can include consistency checks, Masterfile checks, abstract checks, etc. At block 108, the consistency check may be performed. In one or more embodiments of the invention, the data is complete prior to processing the data in process flow 100 which means that all the data that is required by the next level of hierarchy is present in the library. Such data can include but is not limited to timing rules, abstracts, layout, schematics, power rules, checking data, etc. In one example, the consistency check can include analyzing the timing rules for a portion or block of the IC. In addition, the consistency check can ensure the latest data, such as parameters, libraries, etc. are used for analysis. In the event stale data is used, the resulting analysis may incorrectly indicate errors. In a non-limiting example, the data can include multiple different versions of timing rules where the next level of hierarchy can select each of the timing rules in a specific order. An error may occur due to stale data, if the next level hierarchy does not select the most recent data. If the consistency check results in a failure, the file may be returned to block 106 for inspection by the design team and the syntax check can be performed again.

At block 110, a Masterfile check can be performed which compares the file to the Masterfile to determine whether the design is in alignment with the expected design for the IC. If the result of the comparison indicates an error, the file may be returned to block 106 for further inspection and correction by the design team. The updated file will undergo the syntax check and proceed with the remaining checks of the process.

At block 112, an abstract check can be performed. In one or more embodiments of the invention, the abstract check performs a check on the size of the structures in each metal layer. In one or more embodiments, the abstract check can confirm the size of the abstract is the same size as what is expected at the next level of hierarchy. In addition, the abstract check analyzes the ceiling of the abstract, that is the top layer of metal used for a block. This is necessary to create routing contracts. Smaller blocks typically only need a few layers of metal to route the block. The remaining metal layers are then used by integration to integrate/route the design on the next level of hierarchy. If the result of the abstract check results in an error, the file may be returned to block 106 for inspection and correction by the design team. In one or more embodiments of the invention, the checks performed in blocks 108-112 may be performed in parallel, and each of the checks must be completed successfully prior to releasing or unlocking the data.

At block 114, the processer determines whether each of the checks has been successfully completed. If such a determination is made, the lock on the file and data is unlocked or released, as shown in block 116, which allows the data to be merged into the mainstream. That is, the file and data are made available for the next design team or downstream process for further development and analysis. The identification of the errors ensures that reliable and quality is data is provided downstream. However, if such a successful determination is not made, the data remains locked and the data is not allowed to be merged into the mainstream. The lock prevents the data having errors from being introduced to another team further propagating any undetected errors.

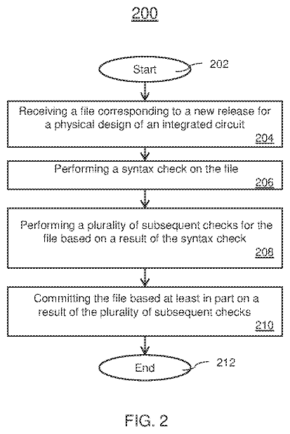

Turning now to FIG. 2, a process flow of a method 200 for performing a release process including consistency checking for processing a physical design is generally shown in accordance with one or more embodiments of the present invention. Method 200 may be implemented in conjunction with any appropriate computer system, such as any system of FIGS. 3-5. Method 200 begins at block 202, and in block 204 a processor is configured to receive a file corresponding to a new release for a physical design of an integrated circuit. In one or more embodiments of the invention, the new release may be locked until the appropriate checks are successfully completed.

At block 206, the processor is configured to perform a syntax check on the file. The processor is configured to analyze the text of the file to determine whether any syntax errors exist. For example, the processor may analyze the file to ensure that a colon is present after each line of code in the file, unnecessary spaces within the code, etc. If the syntax check fails, the file must be updated, for example, the errors must be corrected by a designer or a design team.

At block 208 the processor performs a plurality of subsequent checks for the plurality of files based on a result of the syntax check. The plurality of subsequent checks can include a consistency check, a Masterfile check, and an abstract check. In one or more embodiments of the disclosure, the plurality of subsequent checks is not performed unless the file successfully passes the syntax check without any syntax errors.

The consistency check can include checking the timing rules for each block. Timing rules may define a clock delay between a source and sink or clock skew where the same clock arrives at different components at different times, the difference in time for the clock arriving at different pins is referred to as the clock skew.

The Masterfile check for the layout of the IC can be performed. The segments from each design team can be compared to the Masterfile to ensure compliance with the parameters defined for the overall layout. In one or more embodiments of the invention, a netlist for each segment may be compared to the parameters for a netlist in the Masterfile. The netlist can include a variety of information for the IC including but not limited to the cells used, their interconnections, the area used, and other details.

The abstract check can include performing one or more design rules check (DRC) on each segment of the file. The design rules may comprise a series of parameters provided by IC manufacturers that enable the designer to verify the correctness of a mask set. Design rules are specific to a particular IC manufacturing process. A design rule set specifies certain geometric and connectivity restrictions to ensure sufficient margins to account for variability in IC manufacturing processes, so as to ensure that most of the parts work correctly (i.e., width rules, spacing rules, enclosure rules, etc.).

At block 210 the file may be committed based at least in part on a result of the plurality of subsequent checks. In one or more embodiments of the invention, committing the file makes the file available to a downstream process or other users that have access to the system storing the file. Method 200 ends at block 212.

The process flow of FIG. 2 is not intended to indicate that the operations of method 200 are to be executed in any particular order, or that all of the operations of method 200 are to be included in every case. Additionally, method 200 can include any suitable number of additional operations.

In one or more embodiments of the disclosure, the various checks may be executed in parallel. Additionally, each of the checks must be successfully completed prior to releasing the data to the next phase for processing the integrated circuit chip.

Given that the development and production of an integrated circuit chip is a very complex process, portions of the chip may be assigned to different teams. For example, each of the teams may be responsible for various blocks or hierarchies corresponding to segments of the chip. Subsequently, each teams' data must be collected and integrated for producing the single chip. If the data meets the quality standards, the data can be passed along to the next level of the hierarchy for producing the chip.

Conventionally, the plurality of checks was performed after the data from each team has been merged. The techniques described herein allow for the checking data in advance which reduces the propagation of errors to downstream processes and the potential for re-work.

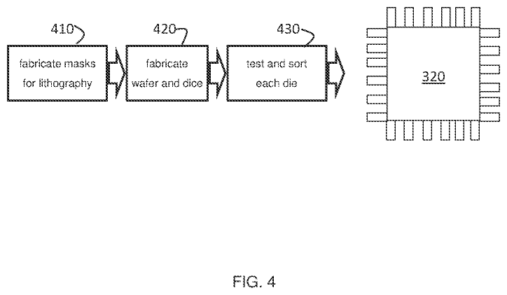

FIG. 3 is a block diagram of a system 300 to perform various consistency checks during the physical design of an integrated circuit chip according to embodiments of the invention. The system 300 includes processing circuitry 310 used to generate the design that is ultimately fabricated into an integrated circuit 320. The steps involved in the fabrication of the integrated circuit 320 are well-known and briefly described herein. Once the physical layout is finalized, based, in part, on performing the consistency checks during the physical design of the integrated circuit chip according to embodiments of the invention to facilitate optimization of the routing plan, the finalized physical layout is provided to a foundry. Masks are generated for each layer of the integrated circuit based on the finalized physical layout. Then, the wafer is processed in the sequence of the mask order. The processing includes photolithography and etch. This is further discussed with reference to FIG. 4.

FIG. 4 is a process flow of a method of fabricating the integrated circuit according to exemplary embodiments of the invention. Once the physical design data is obtained, based, in part, on performing the plurality of error and quality checks, the integrated circuit 320 can be fabricated according to known processes that are generally described with reference to FIG. 4. Generally, a wafer with multiple copies of the final design is fabricated and cut (i.e., diced) such that each die is one copy of the integrated circuit 320. At block 410, the processes include fabricating masks for lithography based on the finalized physical layout. At block 420, fabricating the wafer includes using the masks to perform photolithography and etching. Once the wafer is diced, testing and sorting each die is performed, at block 430, to filter out any faulty die.

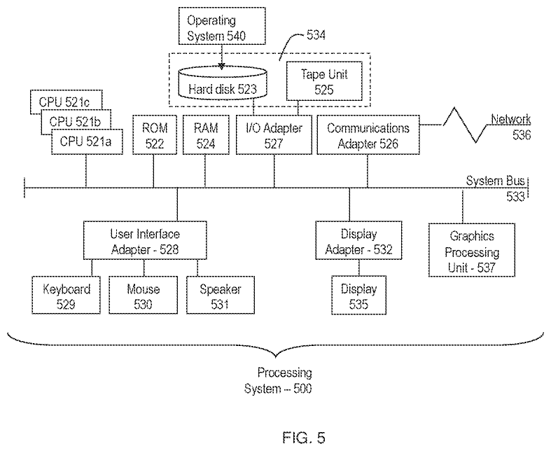

It is understood that one or more embodiments of the present invention are capable of being implemented in conjunction with any other type of computing environment now known or later developed. For example, FIG. 5 depicts a block diagram of a processing system 500 for implementing the techniques described herein. In the embodiment shown in FIG. 5, processing system 500 has one or more central processing units (processors) 521a, 521b, 521c, etc. (collectively or generically referred to as processor(s) 521 and/or as processing device(s)). According to one or more embodiments of the present invention, each processor 521 can include a reduced instruction set computer (RISC) microprocessor. Processors 521 are coupled to system memory (e.g., random access memory (RAM) 524) and various other components via a system bus 533. Read only memory (ROM) 522 is coupled to system bus 533 and can include a basic input/output system (BIOS), which controls certain basic functions of processing system 500.

Further illustrated are an input/output (I/O) adapter 527 and a communications adapter 526 coupled to system bus 533. I/O adapter 527 can be a small computer system interface (SCSI) adapter that communicates with a hard disk 523 and/or a tape storage drive 525 or any other similar component. I/O adapter 527, hard disk 523, and tape storage device 525 are collectively referred to herein as mass storage 534. Operating system 540 for execution on processing system 500 can be stored in mass storage 534. The RAM 522, ROM 522, and mass storage 534 are examples of memory of the processing system 500. A network adapter 526 interconnects system bus 533 with an outside network 536 enabling the processing system 500 to communicate with other such systems.

A display (e.g., a display monitor) 535 is connected to system bus 533 by display adapter 532, which can include a graphics adapter to improve the performance of graphics intensive applications and a video controller. According to one or more embodiments of the present invention, adapters 526, 527, and/or 532 can be connected to one or more I/O busses that are connected to system bus 533 via an intermediate bus bridge (not shown). Suitable I/O buses for connecting peripheral devices such as hard disk controllers, network adapters, and graphics adapters typically include common protocols, such as the Peripheral Component Interconnect (PCI). Additional input/output devices are shown as connected to system bus 533 via user interface adapter 528 and display adapter 532. A keyboard 529, mouse 530, and speaker 531 can be interconnected to system bus 533 via user interface adapter 528, which can include, for example, a Super I/O chip integrating multiple device adapters into a single integrated circuit.

According to one or more embodiments of the present invention, processing system 500 includes a graphics processing unit 537. Graphics processing unit 537 is a specialized electronic circuit designed to manipulate and alter memory to accelerate the creation of images in a frame buffer intended for output to a display. In general, graphics processing unit 537 is very efficient at manipulating computer graphics and image processing and has a highly parallel structure that makes it more effective than general-purpose CPUs for algorithms where processing of large blocks of data is done in parallel.

Thus, as configured herein, processing system 500 includes processing capability in the form of processors 521, storage capability including system memory (e.g., RAM 524), and mass storage 534, input means such as keyboard 529 and mouse 530, and output capability including speaker 531 and display 535. According to one or more embodiments of the present invention, a portion of system memory (e.g., RAM 524) and mass storage 534 collectively store an operating system such as the AIX® operating system from IBM Corporation to coordinate the functions of the various components shown in processing system 500.

Various embodiments of the invention are described herein with reference to the related drawings. Alternative embodiments of the invention can be devised without departing from the scope of this invention. Various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. Moreover, the various tasks and process steps described herein can be incorporated into a more comprehensive procedure or process having additional steps or functionality not described in detail herein.

One or more of the methods described herein can be implemented with any or a combination of the following technologies, which are each well known in the art: a discrete logic circuit(s) having logic gates for implementing logic functions upon data signals, an application specific integrated circuit (ASIC) having appropriate combinational logic gates, a programmable gate array(s) (PGA), a field programmable gate array (FPGA), etc.

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for purposes of illustration and description, but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instruction by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A computer-implemented method for performing integrity checking during physical design data handoffs, the computer-implemented method comprising:
receiving, at a processor, a file corresponding to a new release for a physical design of an integrated circuit;
performing a syntax check on the file;
performing a plurality of subsequent checks on the file based on a result of the syntax check; and
committing the file based at least in part on a result of the plurality of subsequent checks.

2. The computer-implemented method of claim 1, further comprising performing the syntax check for the file prior to performing the plurality of subsequent checks.

3. The computer-implemented method of claim 2, further comprising updating the file responsive to identifying an error in the syntax check.

4. The computer-implemented method of claim 1, wherein the plurality of subsequent checks further comprises a consistency check, a masterfile check, and an abstract check.

5. The computer-implemented method of claim 4, wherein the consistency check comprises identifying an error in timing rules for one or more nets in the integrated circuit.

6. The computer-implemented method of claim 4, wherein the master file check comprises comparing the file to a masterfile for the integrated circuit to identify an error.

7. The computer-implemented method of claim 4, wherein the abstract check comprises identifying an error in a netlist for the integrated circuit.

8. The computer-implemented method of claim 1, further comprises updating the file responsive to identifying an error in any of the plurality of subsequent checks; and
re-performing the syntax check on the updated file.

9. The computer-implemented method of claim 1, wherein the plurality of subsequent checks is performed in parallel.

10. A system for performing integrity checking during physical design data handoffs, the system comprising:
a memory having computer readable instructions;
one or more processors for executing the computer readable instructions, the computer readable instructions controlling the one or more processors is configured to:
receive a file corresponding to a new release for a physical design of an integrated circuit;
perform a syntax check on the file;
perform a plurality of subsequent checks on the file based on a result of the syntax check; and
commit the file based at least in part on a result of the plurality of subsequent checks.

11. The system of claim 10, wherein the one or more processors is further configured to update the file responsive to identifying an error in the syntax check.

12. The system of claim 10, wherein the plurality of subsequent checks further comprises a consistency check, a masterfile check, and an abstract check, wherein the plurality of subsequent checks is performed in parallel.

13. The system of claim 12, wherein the consistency check comprises identifying an error in timing rules for one or more nets in the integrated circuit.

14. The system of claim 12, wherein the masterfile check comprises comparing the file to a masterfile for the integrated circuit to identify an error in the integrated circuit.

15. The system of claim 12, wherein the abstract check comprises identifying an error in a netlist for the integrated circuit.

16. The system of claim 10, wherein the one or more processors is further configured to update the file responsive to identifying an error in any of the plurality of subsequent checks; and
re-perform the syntax check on the update file.

17. A computer program product comprising a computer readable storage medium having program instructions embodied therewith, the program instructions executable by a processor to cause the processor to perform operations comprising:
receiving a file corresponding to a new release for a physical design of an integrated circuit;
performing a syntax check on the file;
performing a plurality of subsequent checks on the file based on a result of the syntax check; and
committing the file based at least in part on a result of the plurality of subsequent checks.

18. The computer program product of claim 17, wherein the plurality of subsequent checks further comprises a consistency check, a masterfile check, and an abstract check, wherein the plurality of subsequent checks is performed in parallel.

19. The computer program product of claim 18, wherein the consistency check comprises identifying an error in timing rules for one or more nets in the integrated circuit,
wherein the masterfile check comprises comparing the file to a masterfile for the integrated circuit to identify an error in the integrated circuit, and
wherein the abstract check comprises identifying an error in a netlist for the integrated circuit.

20. The computer program product of claim 17, wherein the operations further comprise updating the file responsive to identifying an error in any of the plurality of subsequent checks; and
re-performing the syntax check on the update file.
